(19) United States
(12) Patent Application Publication
(10) Pub. No.: US 2009/0242028 A1
(43) Pub. Date: Oct. 1, 2009

(54) CONCENTRATION PHOTOVOLTAIC MODULE

(76) Inventors: Enrico Origlia, Fossano (IT); Roberto Origlia, Fossano (IT); Aldo Origlia, Genola (IT)

Correspondence Address: COLLARD & ROE, P.C., 1077 NORTHERN BOULEVARD, ROSLYN, NY, 11576, US

(21) Appl. No.: 12/383,522

(22) Filed: Mar. 25, 2009

(30) Foreign Application Priority Data
Apr. 1, 2008 (IT) TO2008U000046

(51) Int. Cl. H01L 31/02

(52) U.S. Cl. 136/259

(57) ABSTRACT

It is described a concentration photovoltaic module, comprising a support structure, a linear mirror with parabolic profile mounted on the support structure, and a linear receiver device mounted on the support structure near to the focus of the linear mirror. The linear mirror comprises a pair of half-mirrors separated at the axial plane of the linear mirror. The support structure comprises a pair of corresponding half-mirror supports, in which each of the half-mirrors is formed from a sheet of elastically flexible material, and in which each of the half-mirror supports has a mounting surface suitable for defining and maintaining the parabolic profile of the respective half-mirror. For each half-mirror support an attachment spring is foreseen, arranged along a longitudinal side of the half-mirror support, suitable for forcing the respective half-mirror against the mounting surface.

The present finding refers to a concentration photovoltaic module, comprising a support structure, a linear mirror with parabolic profile mounted on the support structure, and a linear receiver device mounted on the support structure near to the focus of the linear mirror.

The purpose of the present finding is to make a photovoltaic module that simplifies as far as possible the relative mounting and set-up operations, in order to reduce the plant and installation costs linked to the generation of photovoltaic electrical energy.

The apparatus according to the finding is therefore characterised in that the linear mirror comprises a pair of half-mirrors separated at the axial plane of the linear mirror, said support structure comprising a pair of corresponding half-mirror supports, in which each of said half-mirrors is formed from a sheet of elastically flexible material, and in which each of said half-mirror supports has a mounting surface suitable for defining and maintaining the parabolic profile of the respective half-mirror, with elastic attachment means being foreseen for each half-mirror support, arranged along a longitudinal side of the half-mirror support, suitable for forcing the respective half-mirror against the mounting surface of the half-mirror support.

Preferred embodiments of the finding are given in the dependent claims.

Further characteristics and advantages shall become clear from the following description, with particular reference to the attached drawings, given purely as a non-limiting example, in which:

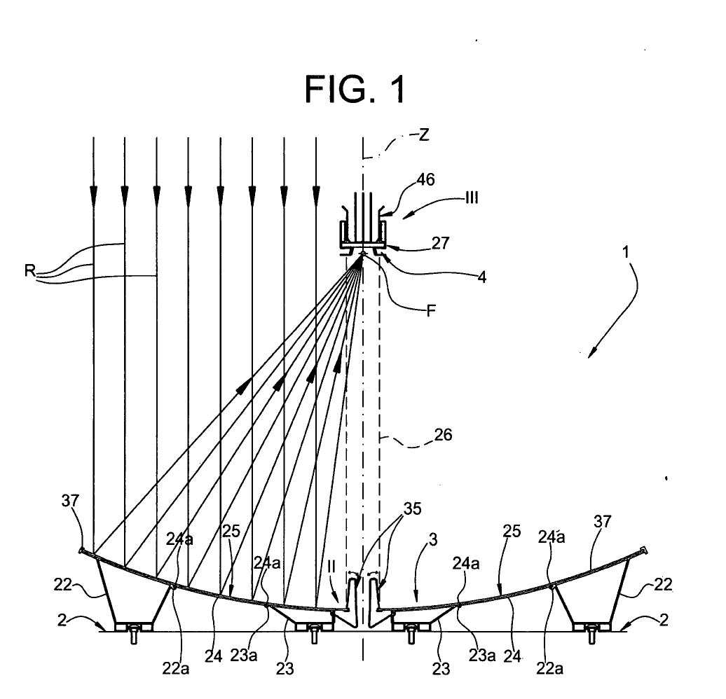

FIG. 1 is a cross sectional view of a concentration photovoltaic module according to the finding;

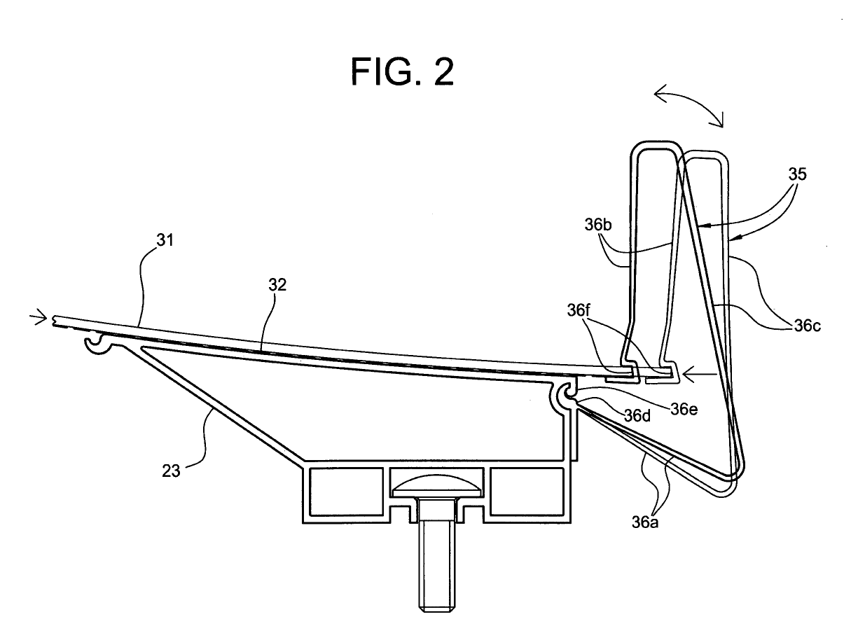

FIG. 2 is a cross section view relative to a detail of a mirror of the module of FIG. 1; and

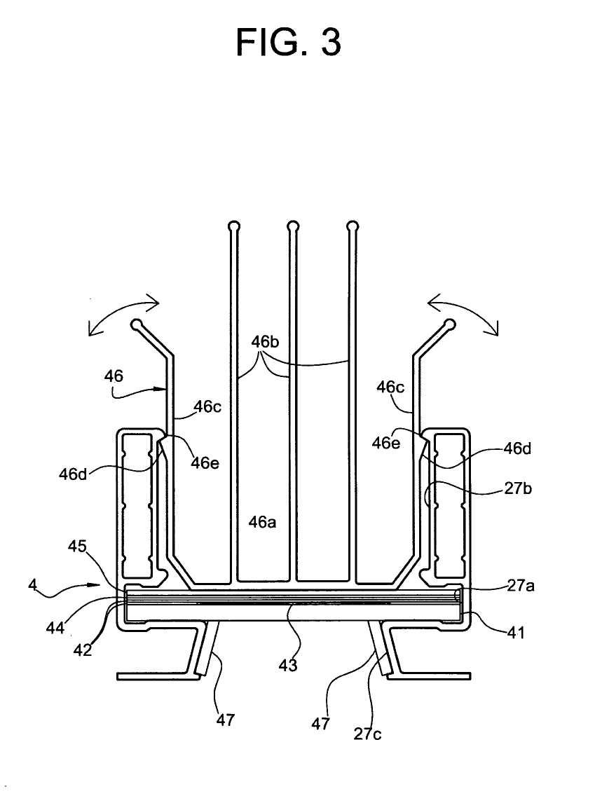

FIG. 3 is a cross sectional view relative to a detail of a receiver device of the module of FIG. 1.

With reference to the figures, a concentration photovoltaic module, wholly indicated with 1, comprises a support structure 2, a linear mirror 3 with parabolic profile mounted on the support structure 2, and a linear receiver device 4 mounted on the support structure 2 near to the focus F of the linear mirror 3.

The operation of the module 1 is that typical of concentration solar modules; sun rays R striking the linear parabolic mirror 3 are reflected onto the receiver device 4 comprising high-efficiency photovoltaic cells, which transform part of the incident energy into electrical energy.

The support structure 2 of the module 1 is suitable for being mounted onto a sun-tracking system (not illustrated), which is not however part of the present finding, and therefore shall not be described any further hereafter. Typically, many modules 1 can be mounted on a single sun-tracking system.

The support structure 2 of the module 1 comprises a plurality of cross beams 21, on which longitudinal beams 22, 23 are mounted formed from profiles with box-shaped section. Such longitudinal beams 22, 23 are arranged according to a symmetrically mirrored configuration with respect to the axial plane z of the mirror 3. In particular, in the illustrated example there are two transversally inner longitudinal beams 23, arranged near to the axial plane z of the mirror 1, and two transversally outer longitudinal beams 22, arranged at the side ends of the mirror 3. Each transversally inner beam 23 is connected to the respective transversally outer beam 22 through a bar (profile) with curved section 24. The connection between such components is allowed by the fact that the side ends of the bar with curved section 24 have bulb-shaped formations 24a that couple with respective throats 22a, 23a formed on the transversally inner beam 23 and on the transversally outer beam 22. The longitudinal beams 22, 23 and the bars with curved section 24 are preferably made from extruded aluminium or laminated steel.

Each group formed from transversally inner beam 23, bar with curved section 24 and transversally outer beam 22 forms a half-mirror support, suitable for supporting a respective half-mirror of the mirror 3, as shall be explained in greater detail hereafter. For this purpose, the transversally inner beam 23, the bar with curved section 24 and the transversally outer beam 22 are shaped so that the half-mirror support formed by them has a mounting surface 25 for the respective half-mirror having a parabolic profile.

Finally, the support structure 2 comprises a series of uprights 26 arranged along the module 1 at the axial plane z, one of which is represented with a broken line in FIG. 1. The up-rights 26 support a bar (profile) frame 27 with box-shaped section in which the receiver device 4 is housed, which can be seen more clearly in FIG. 3. The section of the bar frame 27 is open on the opposite sides in the direction of the axial plane z of the module 1, and defines a central cavity 27a, connected on one side to a first end cavity 27b of smaller size than the central cavity 27a, and on the other side to a second end cavity 27c with trapezoidal section.

As already stated previously, the linear mirror 3 comprises a pair of half-mirrors 31, which are separated at the axial plane z of the linear mirror 1. Each of such half-mirrors 31 is formed from a sheet of elastically flexible material, of course having high specular reflection coefficient. Examples of suitable materials are PMMA and aluminium. The parabolic profile of each half-mirror 31 is defined by the mounting surface 25 of the respective half-mirror support. In this way, the half-mirror supports give the shape to the half-mirrors 31 to ensure their necessary dimensional stability, essential so as to be able to focus the incident solar rays with the maximum possible precision. Between each half-mirror 31 and the respective mounting surface 25 a film 32 of material with lower sliding friction than the materials of the mounting surface and of the mirror, for example made from non-woven polyester, is arranged, which acts as sliding layer to avoid friction between the materials due to the thermal expansion gradient between the material of the mounting surface and the mirroring material.

Along the transversally inner longitudinal side of each half-mirror support elastic attachment means 35 are arranged, as can clearly be seen in FIG. 2. Such elastic attachment means 35 are suitable for forcing the respective half-mirror 31 against the mounting surface 25 of the half-mirror support. This allows the mirrors to be put into operation completely dry, without using glues or additives that keep the mirror in shape. Such mirrors can therefore be cut from flat sheets and do not need forming or gluing operations or processing, since the correct shaping is given directly by the elastic attachment means 35.

In particular, the elastic attachment means 35 comprise a spring-type profile, having bent side wings 36a and 36b connected together by a core 36c. The edge of one of such wings, 36a, is provided with a formation 36d to make a shape-coupling with a corresponding formation 36e formed on the transversally inner beam 23 at which the spring-type profile 35 is mounted. The edge of the other of such wings, 36b, has a throat 36f suitable for receiving a longitudinal edge of the half-mirror 31.

In FIG. 2 the spring-type profile 35 is represented both in relaxed condition, i.e. without the half-mirror 31, and in biased condition, i.e. with the half-mirror 31 mounted. In the latter condition the spring-type profile 35 applies a force on the half-mirror 31 in the transversal direction that, thanks to the fact that the transversally outer edge of the half-mirror support is provided with a stop formation 37 that prevents sliding movements of the half-mirror 31, keeps such a half-mirror 31 in flexed condition against the mounting surface 25.

In this way the spring-type profile 35 gives the half-mirror 31 a coaction such as to keep it in shape during the operating steps. By suitably sizing such a profile, it is possible to ensure an adherence to the underlying structure such as to resist the depression generated by the wind. The presence of a coactive state in the transversal direction also ensures that the half-mirror 31 adheres perfectly to the underlying structure even under the action of thermal expansion. The excursion of the spring is such as to compensate for possible creep and fluage of the half-mirror, always keeping the designed parabolic shape.

With reference to FIG. 3, the receiver device 4 conventionally has a multi-layer strip structure, and has a base formed from a sheet of glass 41 with low iron content, on which a double layer of ethyl vinyl acetate (EVA) 42 is applied, inside which a string of photovoltaic cells 43 is encapsulated, aligned with the axial plane z of the mirror 3. The structure is completed with a Tedlar® film 44 and a sheet 45 of aluminium, arranged on the side facing away from the mirror 3. In the assembly step, the receiver device 4 is inserted into the central cavity 27a along the longitudinal direction of the bar frame 27.

A heat dissipator 46 is mounted in the first end cavity 27b so as to be in contact with the sheet of aluminium 45. In particular, such a dissipator has a contact portion 46a, intended to come into contact with the sheet of aluminium 45, and a plurality of fins 46b, 46c that project from the contact portion 46a and extend up to outside of the first end cavity 27b of the bar frame 27. A pair of side fins 46c of such fins 46b, 46c, arranged on opposite sides of the dissipator 46, have projecting parts 46d suitable for engaging corresponding projecting parts 46e formed on the side walls of the first end cavity 27b of the bar frame 27, so as to obtain a clipped mounting and a certainty of contact with the sheet of aluminium 45.

On the side walls of the second end cavity 27c with trapezoidal section side mirrors 47 are arranged, which are foreseen to also collect the light that, due to possible mechanical imprecisions, optical aberrations of the mirror 3, or approximations of the tracking system, does not precisely strike the receiver device 4, and thus would be dispersed without being transformed into electrical energy.

Of course, without affecting the principle of the finding, the details of construction and the embodiments can be widely varied with respect to what has been described and illustrated purely as an example, without for this reason departing from the scope of protection of the present finding.

1. Concentration photovoltaic module, comprising a support structure, a linear mirror with parabolic profile mounted on the support structure, and a linear receiver device mounted on the support structure near to the focus of the linear mirror,
wherein the linear mirror comprises a pair of half-mirrors separated at the axial plane of the linear mirror, said support structure comprising a pair of corresponding half-mirror supports, in which each of said half-mirrors is formed from a sheet of elastically flexible material, and in which each of said half-mirror supports has a mounting surface suitable for defining and maintaining the parabolic profile of the respective half-mirror, with elastic attachment means being foreseen for each half-mirror support, arranged along a longitudinal side of the half-mirror support, suitable for forcing the respective half-mirror against the mounting surface of the half-mirror support.

2. Module according to claim 1, wherein said elastic attachment means consist of a spring-type profile, having bent side wings connected together by a core, one of said wings being connected through shape-coupling to the respective half-mirror support, and the other being engaged by a longitudinal edge of the respective half-mirror.

3. Module according to claim 1, wherein between each half-mirror and the respective mounting surface a film of material with lower sliding friction than the materials of the mounting surface and the half-mirror is arranged, which acts a sliding layer between them.

4. Module according to claim 1, wherein the half-mirror supports are formed from profiles coupled together and shaped so as to define the respective mounting surfaces for the half-mirrors.

5. Module according to claim 1, wherein said support structure comprises a bar frame with box-shaped section in which the receiver device is housed.

6. Module according to claim 5, wherein the section of the bar frame is open on opposite sides in the direction of the axial plane, and defines a central cavity that houses the receiver device, and it is connected on one side to a first end cavity of smaller size than the central cavity, facing in the opposite direction to the mirror, and on the other side to a second end cavity with trapezoidal section, facing towards the mirror.

7. Module according to claim 6, wherein a heat dissipator is clipped into the first end cavity so as to be in contact with the receiver device.

8. Module according to claim 7, wherein said dissipator has a contact portion, positioned in contact with the receiver device, and a plurality of fins that project from the contact portion and extend up to outside of the first end cavity of the bar frame, a pair of side fins of such fins, arranged on opposite sides of the dissipator, having projecting parts suitable for engaging corresponding projecting parts formed on the side walls of the first end cavity of the bar frame.
